(19) United States
(12) Patent Application Publication
(10) Pub. No.: US 2004/0000375 A1
(43) Pub. Date: Jan. 1, 2004

(54) Plasma etch chamber equipped with multi-layer insert ring

(75) Inventors: Hsiang-Hsing Liu, Gungguan Shiang (TW); Chung-Feng Huang, Hsinchu (TW); Yang-Kai Fan, Hsinchu (TW); Kwang-Niang Tan, Junghe City (TW); Wen-Chin Tseng, Jubei City (TW)

Correspondence Address: TUNG & ASSOCIATES, Suite 120, 838 W. Long Lake Road, Bloomfield Hills, MI, 48302, US

(73) Assignee: Taiwan Semiconductor Manufacturing Co., Ltd.

(21) Appl. No.: 10/184,606

(22) Filed: Jun. 27, 2002

(51) Int. Cl. H01L 21/306

(52) U.S. Cl. 156/345.3; 156/345.48; 156/345.1

(57) ABSTRACT

A multi-layer insert ring for engaging a shadow ring in a plasma etch chamber which includes at least two layers stacked together in an opening of the shadow ring. The multi-layer insert ring may be constructed by two layers or three layers by utilizing ground, reprocessed insert rings resulting in significant cost savings. Each of the layers of the multi-layer insert rings has a planar top surface and a planar bottom surface that is parallel to the planar top surface. Only the top layer need to be replaced after repeated usage of the insert ring in plasma etching processes.

### FIELD OF THE INVENTION

The present invention generally relates to a plasma etch chamber used in semiconductor processing and more particularly, relates to a plasma etch chamber equipped with a multi-layer insert ring for use in semiconductor processing, wherein the insert ring is provided in at least two layers that are stacked together.

### BACKGROUND OF THE INVENTION

In the fabrication of modern integrated circuit devices, one of the key requirements is the ability to construct plugs or interconnects in reduced dimensions such that they may be used in a multi-level metalization structure. The numerous processing steps involved require the formation of via holes for the plug or interconnect in a dimension of 0.5 μm or less for high-density logic devices. For instance, in forming tungsten plugs by a chemical vapor deposition method, via holes in such small dimensions must be formed by etching through layers of oxide and spin-on-glass materials at a high etch rate. A high-density plasma etching process utilizing a fluorine chemistry is thus used for such via formation process.

In a modern etch chamber, an electrostatic chuck (or E-chuck), is frequently used in which the chuck electrostatically attracts and holds a wafer that is positioned on top. The use of E-chuck is highly desirable in the vacuum handling and processing of wafers. In contrast to a conventional method of holding wafers by mechanical clamping means where only slow movement is allowed during wafer handling, an E-chuck can hold and move wafers with a force equivalent to several tens of Torr pressure. Another advantage for the E-chuck is that no particle generation or contamination problem can occur since there are no moving parts acting on the wafer. Moreover, the electrostatic force utilized on an E-chuck is sufficient in preventing bowing of a wafer which normally occurs in mechanical clamping and thus promotes uniform heat transfer over the entire wafer surface.

In an etch chamber equipped with a plasma generating device and an E-chuck, a shadow ring/insert ring combination may be utilized as a seal around the peripheral edge of the wafer. The shadow ring, also known as a focus ring, which normally have an insert ring fitted on an inside peripheral surface is utilized for achieving more uniform plasma distribution over the entire surface of the wafer and for restricting the distribution of the plasma cloud to only the wafer surface area. The uniform distribution function may be further enhanced by a RF bias voltage applied on the wafer during a plasma etching process. Another function served by the shadow ring/insert ring combination is sealing at the wafer level the upper compartment of the etch chamber which contains the plasma from the lower compartment of the etch chamber which contains various mechanical components for controlling the E-chuck. This is important since it prevents the plasma from attacking the hardware components contained in the lower compartment of the etch chamber. In order to survive high temperature and hostile environments, a shadow ring is frequently constructed of a ceramic material such as quartz, while an insert ring is frequently constructed of a sacrificial material such as silicon.

In order to prevent the plasma from affecting the voltage on the electrode of the E-chuck, the electrode positioned in a plasma chamber must be sufficiently isolated from the plasma. In a typical E-chuck positioned in high density plasma, the electrode has a voltage applied to it with respect to a ground reference point. The wafer is referenced back to the same ground reference by the plasma. The effective voltage for the electrostatic clamping of the wafer is then the voltage which appears across the E-chuck dielectric layer between the isolated electrode and the wafer. The voltage applied to the isolated electrode may be positive or negative with respect to the chamber ground. However, the electrostatic force depends on the algebraic difference between the wafer and the isolated electrode.

When the gaps around an E-chuck exceed several debye lengths, plasma may either be generated in the gaps or may be extracted into the gaps. When the plasma contacts the electrostatic chuck which has an imperfect dielectric layer or the E-chuck electrode, a current may flow between the E-chuck and the plasma. The voltage at the E-chuck electrode is therefore affected. Typically, the magnitude of the E-chuck voltage is reduced when a current flows between the chuck and the plasma which leads to a reduction in the electrostatic force. The efficiency of the E-chuck for holding a wafer is therefore affected. Ideally, the solution to the problem is to shield the E-chuck from the high density plasma by limiting gaps between the E-chuck and the shadow ring/insert ring combination around the E-chuck to less than several debye lengths. In such an ideal situation, plasma can be prevented from being generated in the gaps or being extracted into the gaps. Since the ideal equipment conditions cannot be achieved in a manufacturing environment, the generation of plasma in the gaps or the extraction of plasma into the gaps which attacks an insert ring which is fabricated of silicon cannot be avoided. In a normal fabrication environment, it has been found that a silicon insert ring only survives one preventive maintenance cycle or about 2,000 wafers. The corrosion on the top surface of the insert ring is usually severe enough that it must be replaced during a preventive maintenance procedure.

Referring initially to FIG. 1, wherein a conventional etch chamber 10 equipped with a shadow ring 12 around an electrostatic chuck 16 is shown. The etch chamber 10 is equipped with a coil antenna 14 as a plasma source in a reaction chamber 20 formed by a silicon ceiling block 22, a dome-shaped sidewall 24, a chamber wall liner 26 and the electrostatic chuck 16. The dome-shaped sidewall 24 and the chamber wall liner 26 are normally fabricated of quartz. The chamber wall liner 26 may be equipped with an opening for the passage of a wafer paddle in loading and unloading wafers. It may be removed from the vacuum chamber 10 for cleaning.

The shadow ring 12 is positioned inside the plasma reaction chamber 20 which can be lifted up to a process position by positioning pins 32. The positioning pins 32 lift the shadow ring 12 away from the wafer when a wafer is being loaded or unloaded. A multiplicity of cooling gas channels 34 is provided inside the electrostatic chuck 16 at near its top surface 36. A high heat conductivity gas such as helium can be circulated through the cooling gas channels 34 to provide a suitable gas pressure on the bottom side of wafer 30 for transferring heat away from the wafer to the water-cooled E-chuck 16 during an etch process. The supply lines for the cooling gas to channel 34 are not shown. The electrostatic chuck 16 is aligned by an electrostatic chuck collar 38. The etching gas is fed into chamber 20 through gas inlet 28. A thermal coupler 42 is mounted in the silicon ceiling block 22 for controlling temperature.

U.S. Pat. No. 6,022,809, issued to Fan, and assigned to the common assignee of the present invention, discloses a composite shadow ring that has a body portion of a ring shape made of a material substantially of silicon oxide and an insert portion which is intimately jointed to the body portion and is concentric with the body portion. The composite shadow ring 12 is further shown in FIGS. 1 and 1A. As shown in a detailed view in FIG. 1A, the shadow ring 12 is constructed by two major parts of a body portion 18 and an insert portion 48. The body portion has a ring shape and is made of a material that is substantially of silicon oxide, while the insert portion is intimately joined to the body portion 18 by frictional engagement and is juxtaposed to a plasma cloud formed in the etch chamber when the shadow ring 12 is positioned around wafer 30. The insert portion 48 has a diameter that is smaller than a diameter of the body portion 18 and is fabricated of a material that does not generate oxygen upon bombardment by a plasma, particularly by a fluorine-containing plasma. The insert portion 48 is engaged to the body portion 18 by frictional engagement or by any other mechanical means. U.S. Pat. No. 6,022,809 is hereby incorporated by reference in its entirety.

In still another improved design of composite shadow rings, shown in FIGS. 2 and 2A, the composite shadow ring 50, shown in a cross-sectional view in FIG. 2 and in a plane view in FIG. 2A, is constructed by an upper ring 54 and a lower ring 56. An insert ring 62 is inserted against the inner peripheral surface 58 of the composite shadow ring 50. The advantage of this configuration of two flat, concentric rings assembled together by locating pins 60 is that only the upper ring 54 and the insert ring 62 are exposed to plasma ions in the etch chamber and therefore, only the upper ring 54 and the insert ring 62 are subjected to the etching effect of the plasma. As a result, only the upper ring 54 and the insert ring 62 need to be replaced after repeated usage of the composite shadow ring 50 resulting in cost savings. For instance, a commercially available composite shadow ring 50 has a structure of the upper ring 54 fabricated of silicon and the lower ring 56 fabricated of silicon dioxide or quartz. The insert ring 62 is also fabricated of silicon and is considered as a sacrificial part. The effect of erosion on the insert ring 62 is shown in FIGS. 3 and 3A.

The insert ring 62 shown in FIGS. 3 and 3A is etched severely during the plasma etching process. For instance, during each preventive maintenance procedure, it is discovered that the top surface of the insert ring 62 is etched about 10 mil and thus, a new insert ring could only survive two preventive maintenance cycles. Since the insert ring must be fabricated of a material that does not generate oxygen during plasma bombardment, i.e. a material such as silicon, the insert ring is frequently the most expensive component in a plasma etch chamber that needs constant replacement.

It is therefore an object of the present invention to provide an insert ring for engaging a shadow ring in a plasma etch chamber that does not have the drawbacks or shortcomings of the conventional insert rings.

It is another object of the present invention to provide an insert ring for engaging a shadow ring in a plasma etch chamber wherein the insert ring is fabricated in a multi-layer structure.

It is a further object of the present invention to provide an insert ring for engaging a shadow ring in a plasma etch chamber wherein the insert ring is formed in at least two layers.

It is another further object of the present invention to provide an insert ring for engaging a shadow ring in a plasma etch chamber wherein the insert ring is formed in a dual-layer structure.

It is still another object of the present invention to provide an insert ring for engaging a shadow ring in a plasma etch chamber wherein the insert ring is formed in a three-layer structure.

It is yet another object of the present invention to provide a shadow ring assembly for use in a plasma etch chamber that is constructed of a shadow ring and an insert ring that is formed in at least two layers.

It is still another further object of the present invention to provide a plasma etch chamber that utilizes an insert ring in cooperation with a shadow ring wherein the insert ring is formed in at least two layers and supported by a ledge on the inner peripheral surface of the shadow ring.

### SUMMARY OF THE INVENTION

In accordance with the present invention, a shadow ring assembly that incorporates a multi-layer insert ring for use in a plasma etch chamber is provided.

In a preferred embodiment, a shadow ring assembly for use in a plasma etch chamber is provided which includes a shadow ring that has an inner diameter and an outer diameter, the inner diameter defines an inner peripheral surface for engaging in a spaced-apart relationship an outer peripheral surface of a wafer pedestal and for preventing plasma ions from leaking into a lower compartment of the plasma etch chamber that houses the wafer pedestal, the inner peripheral surface of the shadow ring has a ledge formed therein and an upwardly projecting opening adapted for receiving an insert ring; and an insert ring formed in at least two layers for supporting by the ledge in the inner peripheral surface of the shadow ring and for filling the upwardly projecting opening, a top surface of an uppermost layer of the at least two layers of the insert ring is substantially planar with a top surface of the shadow ring when the insert ring is installed in the shadow ring.

In the shadow ring assembly that incorporates a multi-layer insert ring, the insert ring may be formed in two layers of an upper ring and a lower ring. The upper ring and the lower ring may have substantially the same thickness, or the upper ring and the lower ring each may have a thickness that is not more than ½ of the total thickness of the insert ring. Each of the upper ring and the lower ring may have a planar top surface and a planar bottom surface parallel to each other. The shadow ring may be formed of a ceramic material, such as a quartz material. The at least two layers of the insert ring may be formed of a material that is consumable by plasma ions. The insert ring may be formed in three layers of an upper ring, a middle ring and a lower ring, each having substantially the same thickness, or each having a thickness that is one-third of the thickness of the insert ring, or each having a thickness that is at least one-quarter of the thickness of the insert ring.

The present invention is further directed to a plasma etch chamber which is constructed of a chamber enclosure for defining a cavity therein, the chamber enclosure is able to keep a negative pressure of not more than 1 Torr therein; a plasma generating source for producing plasma ions for the cavity; a wafer pedestal for holding a wafer to be processed thereon; a shadow ring that has an inner diameter and an outer diameter, the inner diameter defines an inner peripheral surface for engaging in a spaced-apart relationship an outer peripheral surface of the wafer pedestal and for preventing plasma ions from leaking into a lower compartment of the plasma etch chamber which houses the wafer pedestal, the inner peripheral surface of the shadow ring has a ledge formed therein and an upwardly projecting opening from the ledge adapted for receiving an insert ring; and an insert ring formed in at least two layers for supporting by the ledge in the inner peripheral surface of the shadow ring and for filling the upwardly projecting opening, a top surface of an uppermost layer of the at least two layers of the insert ring is substantially planar with a top surface of the shadow ring when the insert ring is installed in the shadow ring.

In the plasma etch chamber, the insert ring may be formed in two layers of an upper ring and a lower ring, each has a thickness of not more than ½ of the total thickness of the insert ring. The insert ring may further be formed in three layers of an upper ring, a middle ring, and a lower ring, each having a thickness that is at least one-quarter of the thickness of the insert ring. The insert ring may be formed in two layers of an upper ring and a lower ring, each has substantially the same thickness.

The present invention is still further directed to an insert ring for engaging a shadow ring in a plasma etch chamber which is constructed by at least two layers stacked together for engaging an opening in the shadow ring; the at least two layers may further include an upper ring that has a planar top surface and a planar bottom surface, and a lower ring that has a planar top surface for intimately engaging the planar bottom surface of the upper ring and a planar bottom surface; the upper ring and the lower ring each has a thickness that is not more than ½ of the thickness of the insert ring.

In the insert ring for engaging a shadow ring in a plasma etch chamber, the at least two layers stacked together may further include three layers each having a thickness that is not more than one-third of the thickness of the insert ring, or three layers each having a thickness that is more than one-quarter of the thickness of the insert ring.

### BRIEF DESCRIPTION OF THE DRAWINGS

These and other objects, features and advantages of the present invention will become apparent from the following detailed description and the appended drawings in which:

FIG. 1 is a cross-sectional view of a conventional plasma etch chamber equipped with a composite shadow ring.

FIG. 1A is an enlarged, cross-sectional view of the composite shadow ring of the plasma etch chamber of FIG. 1.

FIG. 2 is a cross-sectional view of an improved composite shadow ring.

FIG. 2A is a plane view of the composite shadow ring of FIG. 2.

FIG. 3 is a partial, enlarged, cross-sectional view of a conventional insert ring before used in a plasma etch chamber.

FIG. 3A is a partial, enlarged, cross-sectional view of the insert ring of FIG. 3 after exposed to repeated plasma etching processes.

FIG. 4 is a partial, enlarged, cross-sectional view of a present invention multi-layer insert ring.

FIG. 5 is a partial, enlarged, cross-sectional view of an alternate embodiment of the present invention multi-layer insert ring.

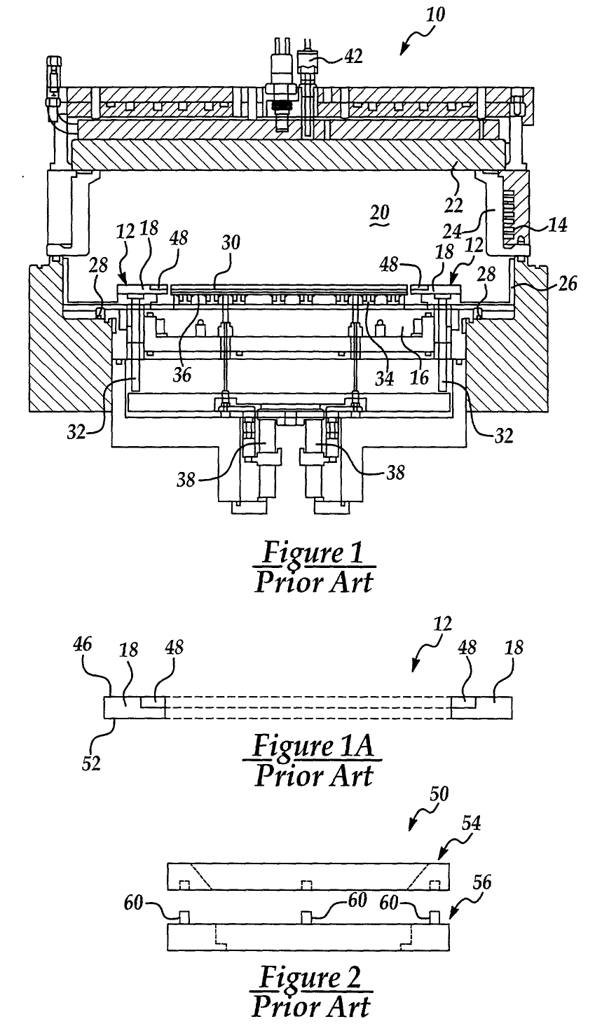

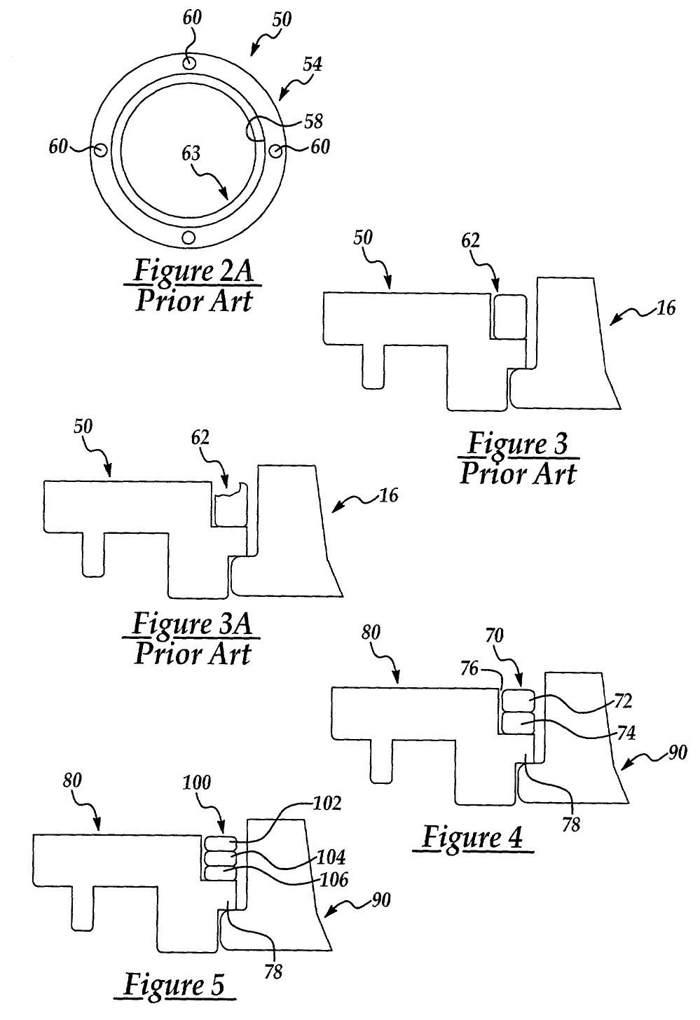

### DETAILED DESCRIPTION OF THE PREFERRED AND ALTERNATE EMBODIMENTS

The present invention discloses an insert ring that is incorporated in a shadow ring for use in a plasma etch chamber. The insert ring is constructed by at least two layer stacked together engaging an opening in the shadow ring. The at least two layers may have an upper ring that has a planar top surface and a planar bottom surface, and a lower ring which has a planar top surface for intimately engaging the planar bottom surface of the upper ring. The upper ring and the lower ring may each have a thickness that is not more than one-half of the total thickness of the insert ring.

In an alternate embodiment, the multi-layer insert ring may be constructed by three layers of insert rings each having a thickness that is not more than one-third of the total thickness of the insert ring.

The invention further discloses a shadow ring assembly that incorporates an insert ring for use in a plasma etch chamber wherein the insert ring is formed in at least two layers for supporting by a ledge formed on the inner peripheral surface of the shadow ring filling an upwardly projecting opening on the ledge. When the insert ring is installed in the shadow ring and situated in a plasma etch chamber, a top surface of the uppermost layer of the multi-layer insert ring should be in the same plane with the top surface of the shadow ring.

The invention still further discloses a plasma etch chamber that is constructed by a chamber enclosure, a plasma generating source, a wafer pedestal, a shadow ring, and a multi-layer insert ring incorporated in the shadow ring.

The present invention multi-layer insert ring may be advantageously fabricated of used insert rings by grinding off a top, etched surface of the used insert ring to approximately half of its original thickness. Two of such reprocessed, or recycled insert rings can then be stacked together on top of a shadow ring for use in a plasma etch chamber. The used insert ring may also be grinded to approximately one-third of its original thickness, and then three of the ground or reprocessed insert rings can then be stacked together on a shadow ring for use in a plasma etch chamber. A typical new insert ring has a thickness of about 3.6 mm. The present invention multi-layer insert ring when stacked together by two separate rings, each may then have a thickness of about 1.8 mm. When three of the ground, reprocessed insert rings are stacked together for use on a shadow ring, each one of the insert rings may have a thickness of about 1.2 mm. As the thickness of the ground, reprocessed insert ring becomes thinner, the handling of the ground rings becomes more difficult due to its extreme brittleness. It is therefore a discovery of the invention that it would not be practical to use more than three ground, reprocessed insert rings stacked together to form a total thickness of 3.6 mm for a new insert ring.

Referring now to FIG. 4, wherein a present invention insert ring 70 is shown. The multi-layer insert ring 70 is constructed by an upper ring 72 and a lower ring 74 stacked together and placed in an opening 76 of the shadow ring 80. The multi-layer insert ring 70 is placed on a ledge 78 of the shadow ring 80. The shadow ring 80 engages an electrostatic chuck 90, as shown in FIG. 4.

In the multi-layer insert ring 70, the upper ring 72 and the lower ring 74 each may have a thickness that is one-half of the thickness of the total insert ring 70. For a frequently used, commercial insert ring that has a thickness of about 3.6 mm, each of the upper rings 72 and the lower ring 74 has a thickness of about 1.8 mm. The upper ring 72 and the lower ring 74 may also have different thicknesses. For instance, when one of the upper rings 72 and the lower rings 74 has a thickness more than one-half of the thickness of the insert ring 70, then the other one of the upper rings 72 and lower rings 74 should have a thickness less than one-half of the thickness of the insert ring 70. As shown in FIG. 4, the present invention multi-layer ring 70 utilizes advantageously a ground, reprocessed insert ring such as that previously shown in FIG. 3A.

In an alternate embodiment, shown in FIG. 5, a multi-layer insert ring 100 which consists of an upper ring 102, a middle ring 104 and a lower ring 106 is shown. The three-layered insert ring 100 may have a total thickness of about 3.6 mm, and thus each one of the upper rings 102, middle rings 104 and lower rings 106 would have a thickness of about 1.2 mm when the three rings have substantially the same thickness. The word “substantially” used in this writing indicates a range of value that is ±10% of the average value given. In the configuration shown in FIG. 5, when one of the three rings 102, 104 and 106 has a thickness larger than one-third of the thickness of the multi-layered insert ring 100, then the other two layers must have a thickness smaller than one-third of the thickness of the total ring 100.

The present invention multi-layer insert ring for use on a shadow ring in a plasma etch chamber has therefore been amply described in the above description and in the appended drawings of FIGS. 4 and 5.

While the present invention has been described in an illustrative manner, it should be understood that the terminology used is intended to be in a nature of words of description rather than of limitation.

Furthermore, while the present invention has been described in terms of one preferred and one alternate embodiment, it is to be appreciated that those skilled in the art will readily apply these teachings to other possible variations of the inventions.

The embodiment of the invention in which an exclusive property or privilege is claimed are defined as follows.

What is claimed is:

1. A shadow ring assembly for use in a plasma etch chamber comprising:
a shadow ring having an inner diameter and an outer diameter, said inner diameter defines an inner peripheral surface for engaging in a spaced-apart relationship an outer peripheral surface of a wafer pedestal and for preventing plasma ions from entering into a lower compartment of said plasma etch chamber that houses said wafer pedestal, said inner peripheral surface of the shadow ring having a ledge formed therein and an upwardly projecting opening adapted for receiving an insert ring; and
an insert ring formed in at least two layers for supporting by said ledge in said inner peripheral surface of said shadow ring and for filling said upwardly projecting opening, a top surface of an uppermost layer of said at least two layers of said insert ring being substantially planar with a top surface of said shadow ring when said insert ring is installed in said shadow ring.

2. A shadow ring assembly for use in a plasma etch chamber according to claim 1, wherein said insert ring being formed in two layers of an upper ring and a lower ring.

3. A shadow ring assembly for use in a plasma etch chamber according to claim 2, wherein said upper ring and said lower ring have substantially the same thickness.

4. A shadow ring assembly for use in a plasma etch chamber according to claim 2, wherein said upper ring and said lower ring each having a thickness that is not more than one-half of the thickness of said insert ring.

5. A shadow ring assembly for use in a plasma etch chamber according to claim 2, wherein each of said upper ring and said lower ring having a planar top surface and a planar bottom surface parallel to each other.

6. A shadow ring assembly for use in a plasma etch chamber according to claim 1, wherein said shadow ring is formed of a ceramic material.

7. A shadow ring assembly for use in a plasma etch chamber according to claim 1, wherein said shadow ring is formed of quartz.

8. A shadow ring assembly for use in a plasma etch chamber according to claim 1, wherein said at least two layers of said insert ring being formed of a material that is consumable by plasma ions.

9. A shadow ring assembly for use in a plasma etch chamber according to claim 1, wherein said at least two layers of insert ring being formed of silicon.

10. A shadow ring assembly for use in a plasma etch chamber according to claim 1, wherein said insert ring being formed in three layers of an upper ring, a middle ring and a lower ring.

11. A shadow ring assembly for use in a plasma etch chamber according to claim 10, wherein said upper ring, said middle ring and said lower ring each having substantially the same thickness.

12. A shadow ring assembly for use in a plasma etch chamber according to claim 10, wherein said upper ring, said middle ring and said lower ring each having a thickness that is one-third of the thickness of said insert ring.

13. A shadow ring assembly for use in a plasma etch chamber according to claim 10, wherein said upper ring, said middle ring and said lower ring each having a thickness that is at least one-quarter of the thickness of said insert ring.

14. A plasma etch chamber comprising:
a chamber enclosure for defining a cavity therein, said chamber enclosure being able to maintain a pressure of not higher than 1 Torr therein;
a plasma generating source for producing plasma ions for said cavity;
a wafer pedestal for holding a wafer to be processed thereon;
a shadow ring having an inner diameter and an outer diameter, said inner diameter defines an inner peripheral surface for engaging in a spaced-apart relationship an outer peripheral surface of said wafer pedestal and for preventing plasma ions from leaking into a lower compartment of said plasma etch chamber that houses said wafer pedestal, said inner peripheral surface of the shadow ring having a ledge formed therein and an upwardly projecting opening from the ledge adapted for receiving an insert ring; and
an insert ring formed in at least two layers for supporting by said ledge in said inner peripheral surface of said shadow ring and for filling said upwardly projecting opening, a top surface of an uppermost layer of said at least two layers of said insert ring being substantially planar with a top surface of said shadow ring when said insert ring is installed in said shadow ring.

15. A plasma etch chamber according to claim 14, wherein said insert ring being formed in two layers of an upper ring and a lower ring, each having a thickness not more than one-half of the thickness of said insert ring.

16. A plasma etch chamber according to claim 14, wherein said insert ring being formed in three layers of an upper ring, a middle ring, and a lower ring, each having a thickness that is at least one-quarter of the thickness of said insert ring.

17. A plasma etch chamber according to claim 14, wherein said insert ring being formed in two layers of an upper ring and a lower ring, each having substantially the same thickness.

18. An insert ring for engaging a shadow ring in a plasma etch chamber comprising:
at least two layers stacked together for engaging an opening in said shadow ring;
said at least two layers further comprises:
an upper ring having a planar top surface and a planar bottom surface, and
a lower ring having a planar top surface for intimately engaging said planar bottom surface of said upper ring and a planar bottom surface;
said upper ring and said lower ring each having a thickness that is not more than one-half of the thickness of said insert ring.

19. An insert ring for engaging a shadow ring in a plasma etch chamber according to claim 18, wherein said at least two layers stacked together further comprises three layers each having a thickness that is not more than one-third of the thickness of said insert ring.

20. An insert ring for engaging a shadow ring in a plasma etch chamber according to claim 18, wherein said at least two layers stacked together further comprises three layers each having a thickness that is more than one-quarter of the thickness of said insert ring.
